(19) United States
(12) Patent Application Publication
(10) Pub. No.: US 2023/0127021 A1
(43) Pub. Date: Apr. 27, 2023

(54) TECHNOLOGIES FOR FAN MECHANISM WITH AUTOMATICALLY ADJUSTBLE SIDE VENTING

(71) Applicant: Intel Corporation, Santa Clara, CA (US)

(72) Inventors: Chunlin Bai, Qingyang District (CN); Xiyong Tian, Beijing (CN); Baoci Sun, Los Gatos, CA (US)

(73) Assignee: Intel Corporation, Santa Clara, CA (US)

(21) Appl. No.: 18/146,311

(22) Filed: Dec. 23, 2022

(30) Foreign Application Priority Data
Dec. 22, 2022 (CN) PCT/CN2022/140880

(51) Int. Cl. H05K 7/20; G06F 1/20

(52) U.S. Cl. CPC H05K 7/20172; G06F 1/203

(57) ABSTRACT

Techniques for fan mechanisms with adjustable side vents are disclosed. In one embodiment, a fan housing has several side vents that can direct airflow to components around the fan housing. Vent covers can block the vents, directing the airflow to the primary vent and the heatsink for the processor and other components. When the speed of a fan in the fan housing is increased, the vent covers open, directing airflow to components around the fan housing. In another embodiment, several vent channels are defined in the vent housing. A motor connected to a vent barrier can move the vent barrier to block or unblock the vent channels, allowing for control of airflow. In another embodiment, a fan channel module with one or more vent channels can be attached to the fan housing, allowing for a flexible array of airflow patterns for the same fan housing.

### CROSS-REFERENCE TO RELATED APPLICATIONS

This application claims the benefit of priority under 35 U.S.C. § 119(a) to PCT International Application Serial No. PCT/CN2022/140880 filed on Dec. 22, 2022, and entitled TECHNOLOGIES FOR FAN MECHANISM WITH AUTOMATICALLY ADJUSTABLE SIDE VENTING. The prior application is hereby incorporated by reference in its entirety.

### BACKGROUND

Thermal management is important for many computing devices, including small form factor devices such as laptops. In order to provide both cooling and a compact footprint, one common approach for cooling in laptops is for a fan to cool a heatsink that is thermally coupled to heat pipes that connect to various components of a laptop. In order to provide thermal management for additional components, a decentralized layout and thermal spreading material may be used.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified drawing of at least one embodiment of a compute device.

FIG. 2 is a simplified drawing of at least one embodiment of a bottom side of the compute device of FIG. 1.

FIG. 3 is a simplified drawing of at least one embodiment of a bottom side of the compute device of FIG. 1 with a portion of a bottom cover removed, showing one embodiment of side vents on a fan housing.

FIG. 4 is a simplified drawing of at least one embodiment of a bottom side of the compute device of FIG. 1 with a portion of a bottom cover removed, showing one embodiment of the side vents open.

FIG. 5 is a simplified plot showing static pressure as a function of airflow.

FIG. 6 is a simplified drawing of at least one embodiment of a bottom side of the compute device of FIG. 1 with a portion of a bottom cover removed, showing one embodiment of side vents on a fan housing.

FIG. 7 is a simplified drawing of at least one embodiment of a bottom side of the compute device of FIG. 1 with a portion of a bottom cover removed, showing one embodiment of side vents open.

FIG. 8 is a simplified drawing of a vent cover with torsion springs.

FIG. 9 is a simplified drawing of at least one embodiment of a bottom side of the compute device of FIG. 1 with a portion of a bottom cover removed, showing one embodiment of side vents open.

FIG. 10 is a simplified drawing of a housing for a fan with variable side-venting configurations.

FIG. 11 is a simplified drawing of a housing for a fan with variable side-venting configurations.

FIG. 12 is a simplified drawing of a housing for a fan with variable side-venting configurations.

FIG. 13 is a simplified drawing of a housing for a fan with variable side-venting configurations.

FIG. 14 is a simplified drawing of a housing for a fan with a side vent and a detachable module for variable side vents, with the detachable module attached.

FIG. 15 is a simplified drawing of a housing for a fan with a side vent and a detachable module for variable side vents, with the detachable module detached.

FIG. 16 is a simplified block diagram of at least one embodiment of a compute device.

FIG. 17 is a simplified block diagram of at least one embodiment of an environment that may be established by the compute device of FIG. 16.

FIG. 18 is a simplified flow diagram of at least one embodiment of a method for controlling a fan of a compute device.

### DETAILED DESCRIPTION OF THE DRAWINGS

In various embodiments disclosed herein, a compute device may include an overlay component that can be used as, e.g., an additional input surface. The compute device may include circuitry to sense touches on the overlay component, such as by a stylus or by a finger of a user. In some embodiments, the overlay component may include a display, such as an electronic paper display or organic light-emitting diode (OLED) display. In one embodiment, the overlay component is on the base portion of compute device and can unfold to cover part of the keyboard. In another embodiment, the overlay component can move between covering the display and covering the keyboard. In some embodiments, such an overlay component may be passive, allowing for the display to be seen through the overlay component while the overlay component is near the display, while appearing opaque or translucent while the overlay component is near the keyboard. In other embodiments, the overlay component may be electrically switchable between an opaque state and a clear state.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, electromagnetic radiation). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Optical components such as fibers or waveguides may be “connected” if the gap between them is small enough that light can be transferred from one fiber or waveguide to another fiber or waveguide without any intervening optical elements, such as a lens or mirror. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

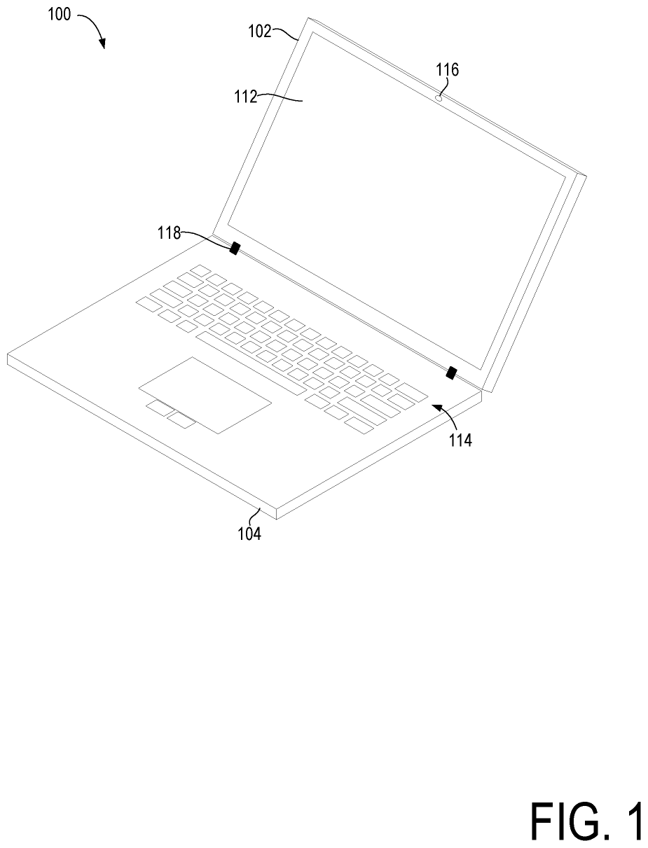

Referring now to FIG. 1, an illustrative compute device 100 includes a lid portion 102 and a base portion 104. The lid portion 102 includes a display 112, and the base portion 104 includes a keyboard 114. The illustrative compute device 100 is embodied as a laptop with a clamshell configuration. The illustrative compute device 100 can be in an open configuration (shown in FIG. 1) or a closed configuration, with the lid portion 102 positioned on top of the base portion 104 with the display 112 facing downwards toward the base portion 104. Additionally or alternatively, the compute device 100 may be embodied as a laptop with additional configurations. For example, the compute device 100 may be a laptop with a display that can rotate up to 360°, allowing the compute device 100 to be in a book configuration, a tablet configuration, etc. The compute device 100 may be a 2-in-1 device, with a lid portion 102 that can separate from the base portion 104. In some embodiments, the compute device 100 may be another portable or nonportable electronic device, such as a cell phone, a tablet, a desktop computer, a server computer, etc.

The illustrative lid portion 102 has a display 112. The display 112 may be any suitable size and/or resolution, such as a 5-18 inch display, with a resolution from 340×480 to 3820×2400. The display 112 may use any suitable display technology, such as LED, OLED, QD-LED, electronic paper display, etc. The display 112 may be a touchscreen display. The lid portion 102 may also include a camera 116. The camera 116 may include one or more fixed or adjustable lenses and one or more image sensors. The image sensors may be any suitable type of image sensors, such as a CMOS or CCD image sensor. The camera 116 may have any suitable aperture, focal length, field of view, etc. For example, the camera 116 may have a field of view of 60-110° in the azimuthal and/or elevation directions. In some embodiments, the camera 116 has a field of view that can capture the entire overlay component 106. In the illustrative embodiment, one or more hinges 118 joins the base portion 104 and the lid portion 102.

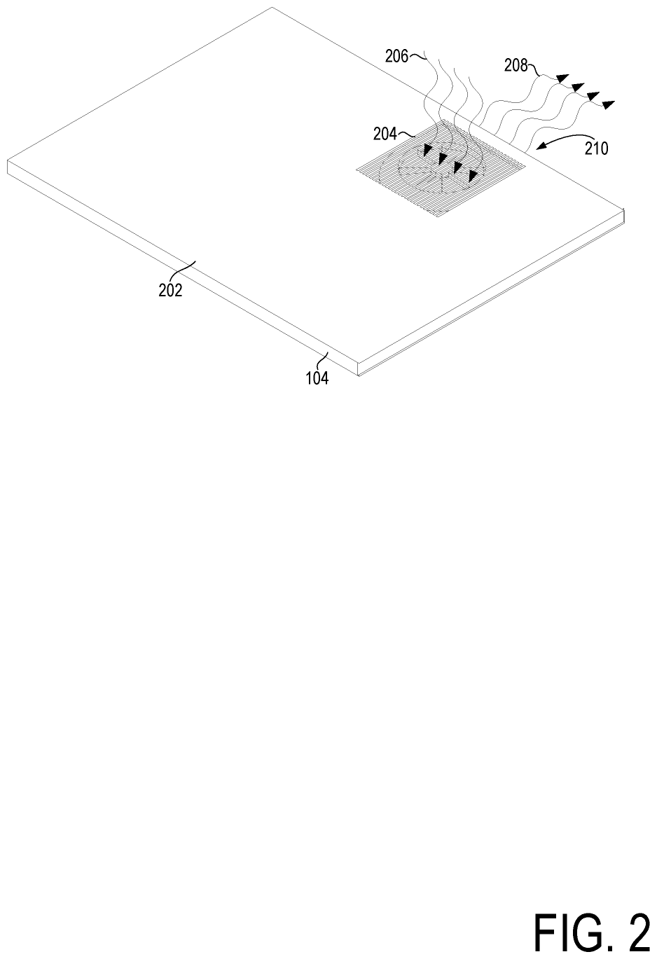

Referring now to FIG. 2, in one embodiment, a view of the bottom of the compute device 100 is shown. A cover 202 is on the bottom of the base portion 104. Air intake holes 204 are defined in the cover to allow intake air 206 to pass through the base portion 104. Exhaust air 208 is expelled from a primary vent 210 of a fan assembly, as shown in more detail below.

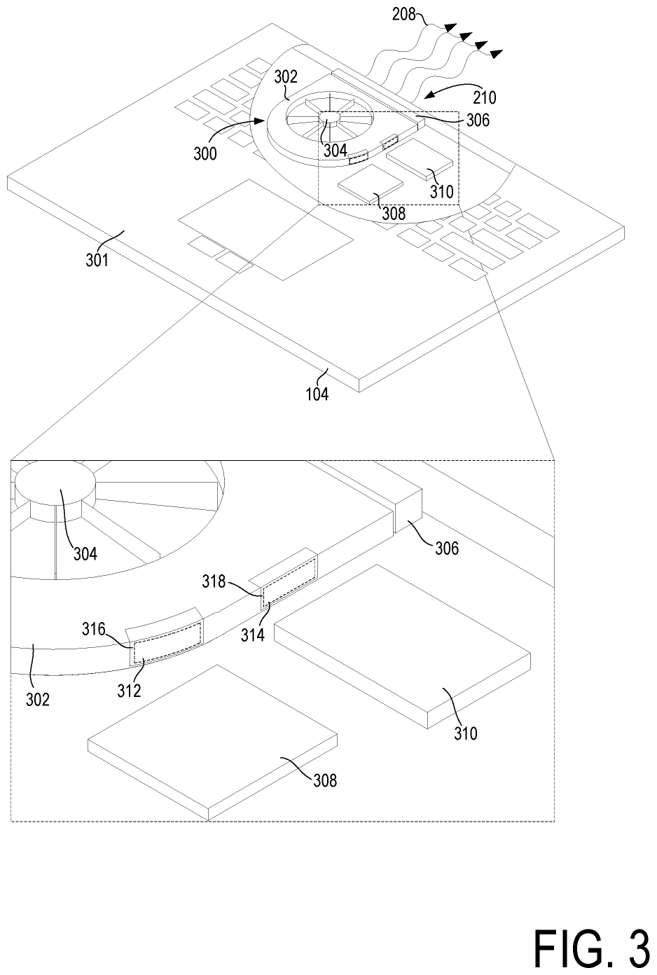

Referring now to FIG. 3, in one embodiment, a view of the base portion 104 is shown with a portion of a top cover 301 removed. A fan assembly 300 is positioned above the air intake holes 204. The fan assembly 300 includes a fan housing 302 and a variable-speed fan 304. In use, the fan 304 turns, pulling air in from the air intake holes 204 and pushing air to the outside of the blades of the fan 304, causing air to flow out of the primary vent 210. A heat sink 306 is positioned at the primary vent 210 of the fan assembly 300. The heat sink 306 is thermally coupled to one or more components of the compute device 100, such as a processor, memory, graphics card, storage device, etc. The heat sink 306 may be thermally coupled to one or more components in any suitable manner, such as a heat pipe. Additional components 308, 310 are near the fan assembly 300. Additional components 308, 310 may be components that may require cooling but may not be cooled by the heat sink 306. In the illustrative embodiment, the components 308, 310 may be, e.g., storage, memory, application-specific integrated circuits (ASICs), and/or any other suitable component.

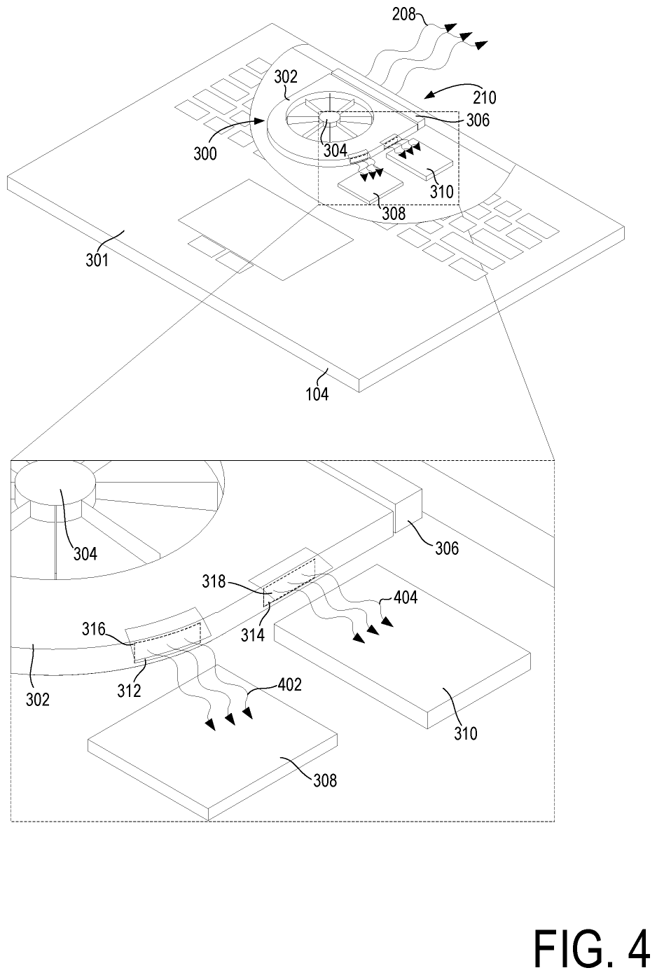

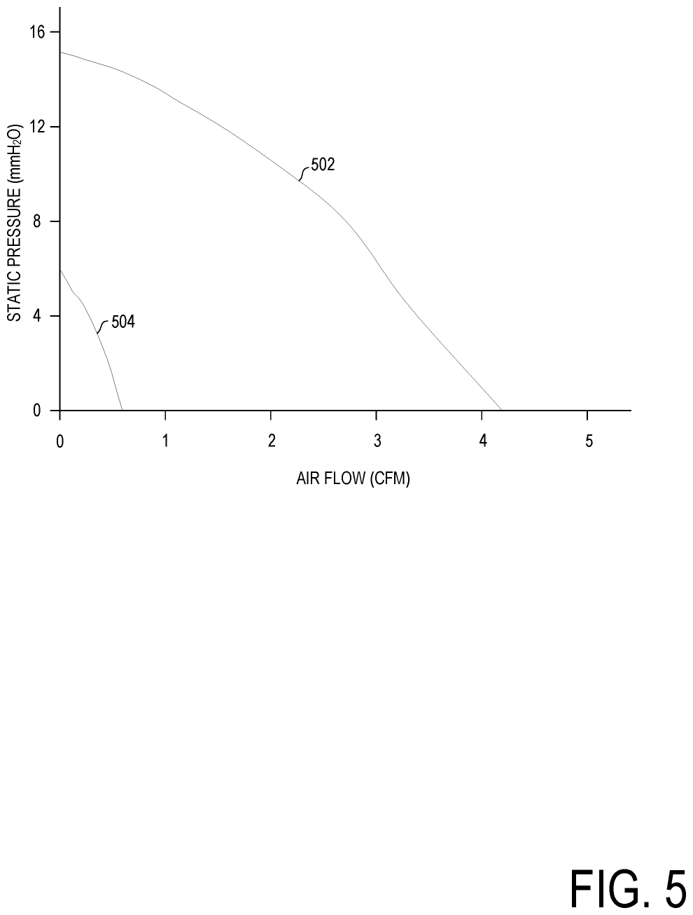

As shown in the zoomed-in view in FIG. 3, side vents 312, 314 are defined in the side of the fan housing 302. Vent covers 316, 318 cover the side vents 312, 314, preventing air from exiting the side vents 312. When the speed of the fan 304 passes a threshold, the pressure behind the vent covers 316, 318 pushes the vent covers open 316, 318, allowing airflows 402, 404 to pass over the components 308, 310, as shown in FIG. 4. One way to characterize performance of the fan 304 and the vents 210, 312, 314 is with a PQ curve, which shows static pressure as a function of airflow. A PQ curve for one embodiment of the main vent 210 is shown as curve 502 in FIG. 5, and a PQ curve for one embodiment of the side vents 312, 314 is shown as curve 504 in FIG. 5.

In one embodiment, the vent covers 316, 318 may be fabric. Fabric is light and can easily be pushed out of the way by the airflows 402, 404. The fabric vent covers 316, 318 may also easily deform and exhibit wave motion. The fabric vent covers 316, 318 may be fixed to the fan housing 302 in any suitable manner, such as a strong adhesive or pressure gasket for the fan assembly 300.

In use, in the illustrative embodiment, the fan 304 may operate at a low speed some of the time, such as when power usage is relatively low, the components 308, 310 do not require additional cooling, or both. At a later time, components 308, 310 may require additional cooling. For example, the compute device 100 may be performing a particular task that uses one or both of the components 308, 310, heating them up. The speed of the fan 304 may be increased, which increases the pressure at the fabric vent covers 316, 318. The fabric vent covers 316, 318 can open up, allowing airflows 402, 404 to cool off components 308, 310, respectively. When the speed of the fan 304 is reduced or the fan 304 is turned off, the fabric vent covers 316, 318 close.

The fan housing 302 may be made of any suitable material. In the illustrative embodiment, the fan housing 302 is made of plastic. In other embodiments, the fan housing 302 may be made of metal, such as aluminum or steel. The fan housing 302 may have any suitable dimensions, such as a height of 5-25 millimeters, a width of 10-120 millimeters, and a length of 10-120 millimeters. The fan 304 may be made of a similar material as the fan housing 302. The fan 304 may have any suitable dimensions, such as a height of 5-25 millimeters and a diameter of 10-100 millimeters. The fan 304 may be able to operate at any suitable maximum speed, such 2,000-10,000 revolutions per minute (RPM). The fan 304 may be able to operate at any speed between zero and its maximum speed, or the fan 304 may have one or more fixed speed settings. The fan 304 may be able to move any suitable amount of air, such as 0-10 cubic feet per minute through the primary vent 210 and 0-2 cubic feet per minute through the vents 312, 314.

In some embodiments, the compute device 100 may include more than one fan assembly 300, such as 2-4 fan assemblies 300. The fan housing 302 may have any suitable number of side vents 312, 314, such as 1-10. The side vents 312, 314 may have any suitable dimensions, such as a height of 2-25 millimeters and a length of 2-50 millimeters.

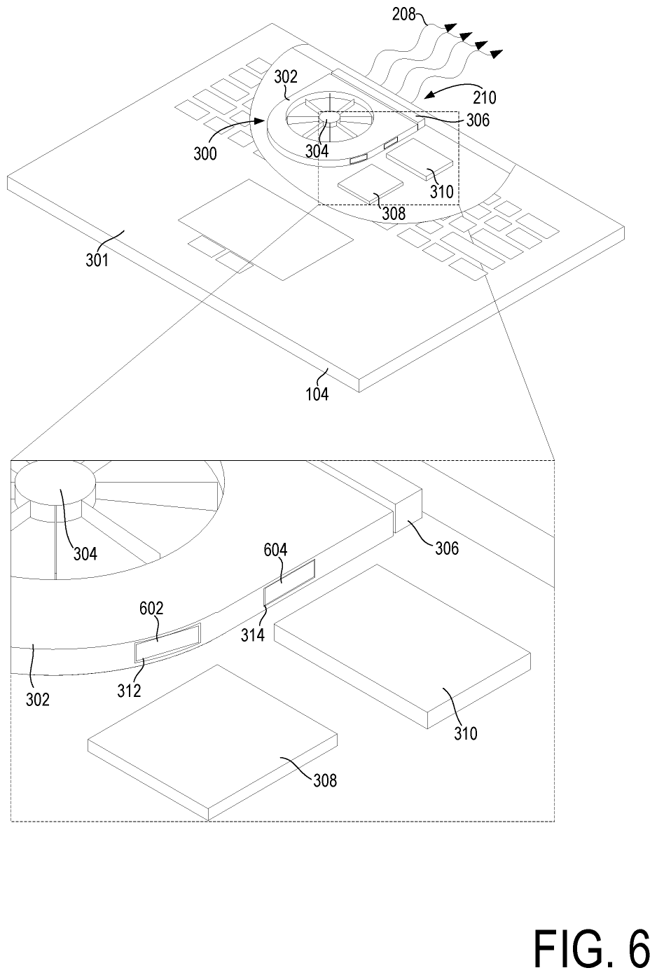

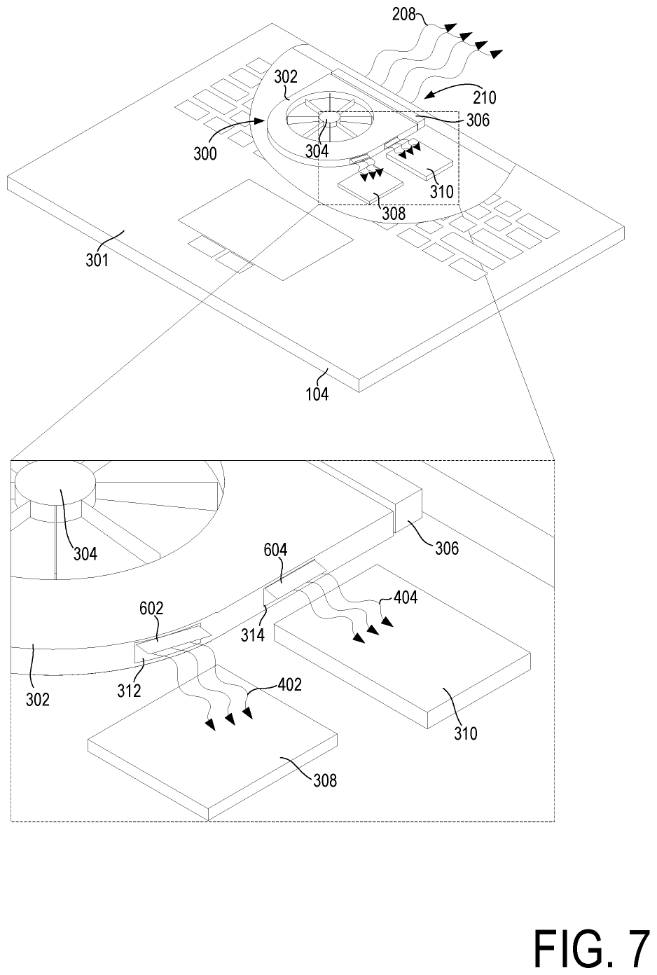

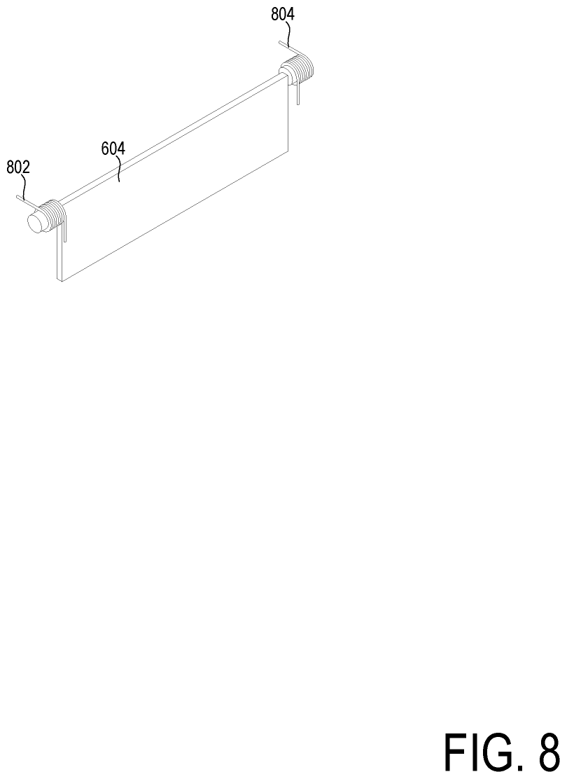

Referring now to FIGS. 6 and 7, in one embodiment, the side vents 312, 314 may be covered by relatively rigid vent covers 602, 604. The vent covers 602, 604 are held in place by torsion springs 802, 804 (see FIG. 8). When the speed of the fan 304 passes above a threshold, the pressure overcomes the force from the springs 802, 804, pushing the vent covers 602, 604 open. When the speed of the fan 304 passes below a threshold, the vent covers 602, 604 are closed by a combination of the springs 802, 804 and gravity. The vent covers 602, 604 may be any suitable material, such as plastic, mylar, metal, etc.

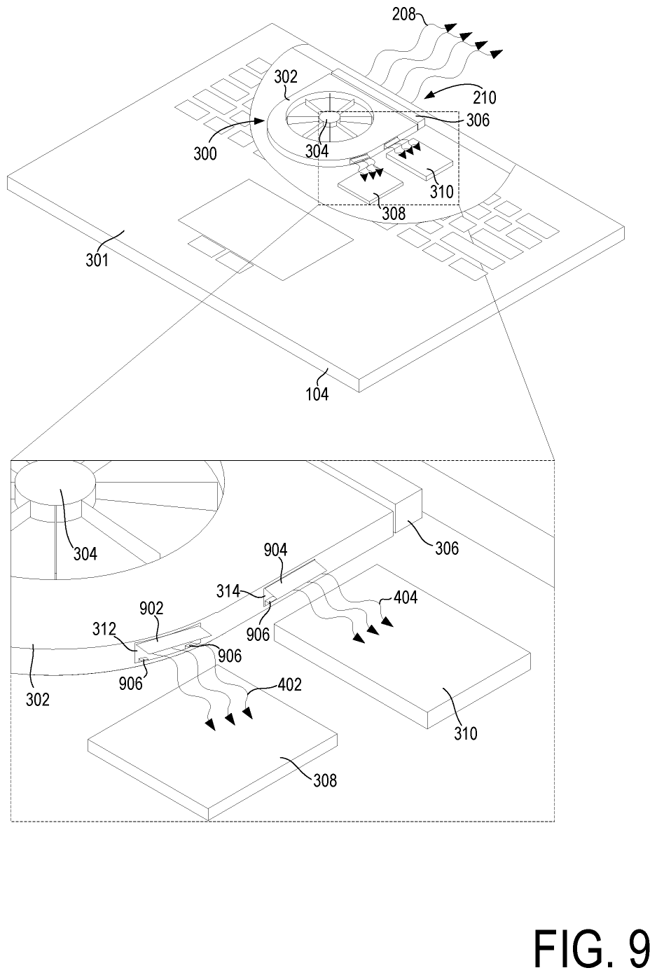

Referring now to FIG. 9, in one embodiment, the side vents 312, 314 may be covered by magnetic vent covers 902, 904. The vent covers 902, 904 are held in place by magnets 906 mounted in the fan housing 302 near the vents 312, 314. When the speed of the fan 304 passes above a threshold, the pressure overcomes the force from the magnets 906, pushing the vent covers 902, 904 open. When the speed of the fan 304 passes below a threshold, the vent covers 902, 904 are closed, either by gravity, springs 802, 804, or a magnetic force. The vent covers 902, 904 may be made of any suitable material, such as iron or steel.

It should be appreciated that the approaches described above for the vent covers are merely several possible embodiments, and other embodiments are possible as well. Additionally, the embodiments described above may be used in any suitable combination with each other.

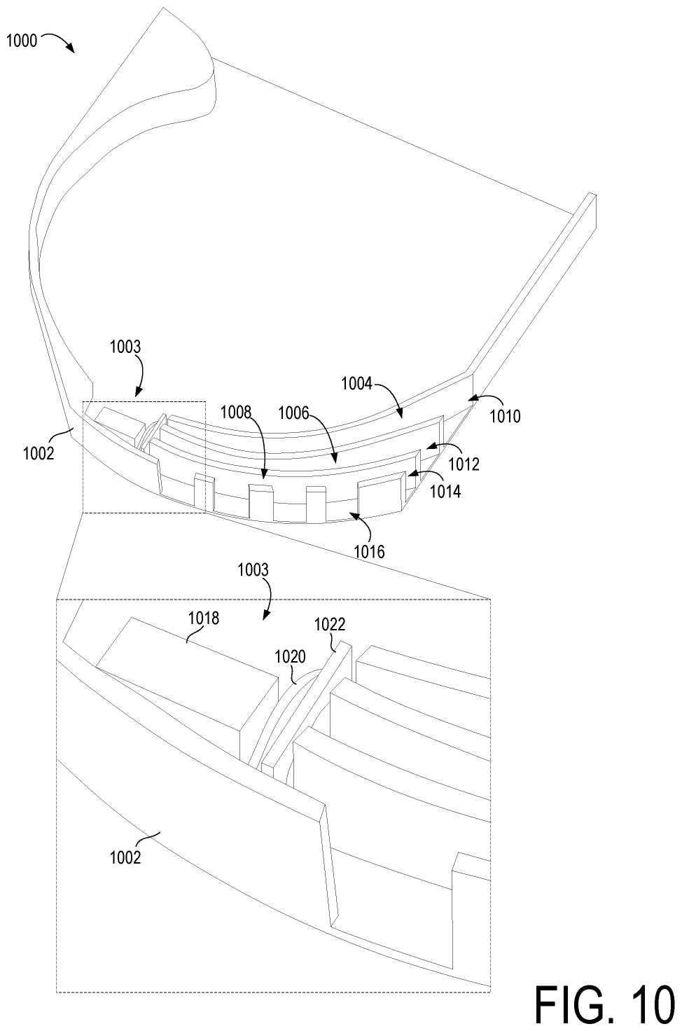

Referring now to FIG. 10, in one embodiment, a fan assembly 1000 is shown. The fan assembly 1000 may be integrated into a compute device 100 in a similar manner as the fan assembly 300. The fan assembly 1000 includes a fan housing 1002. The fan and top cover are not shown in FIG. 10 in the interest of clarity, but the fan for the fan assembly 1000 may be similar to the fan 304 for the fan housing 302. Several vent channels 1004, 1006, 1008 are defined in the fan housing 1002. The vent channels 1004, 1006, 1008 lead to vents 1010, 1012, and 1014 and 1016, respectively. A motor assembly 1003 is positioned at one end of the vent channels 1004, 1006, 1008.

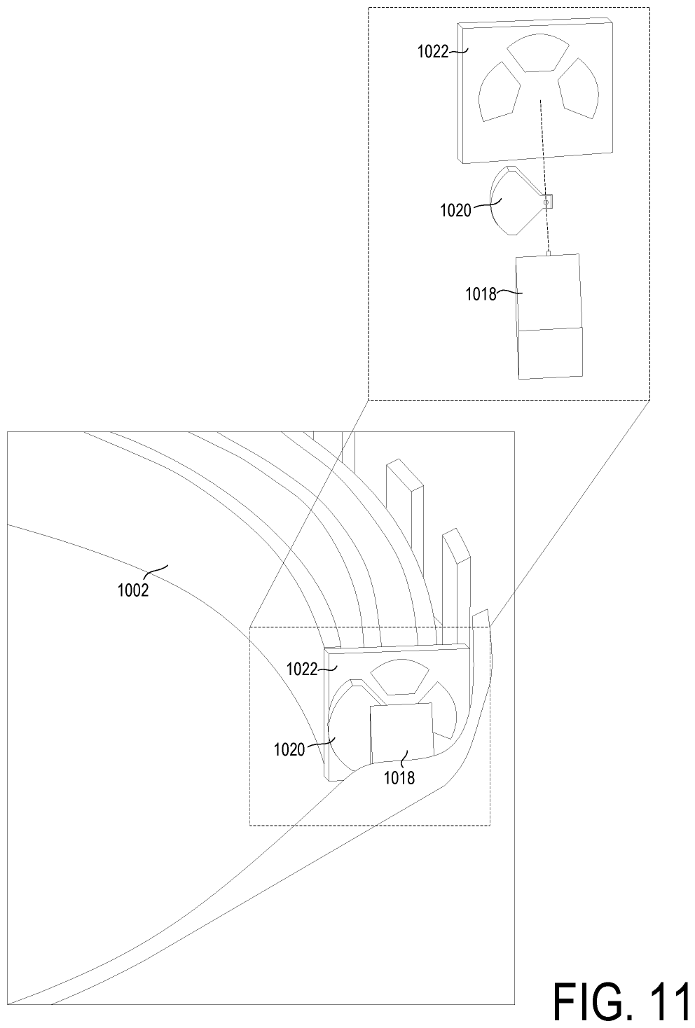

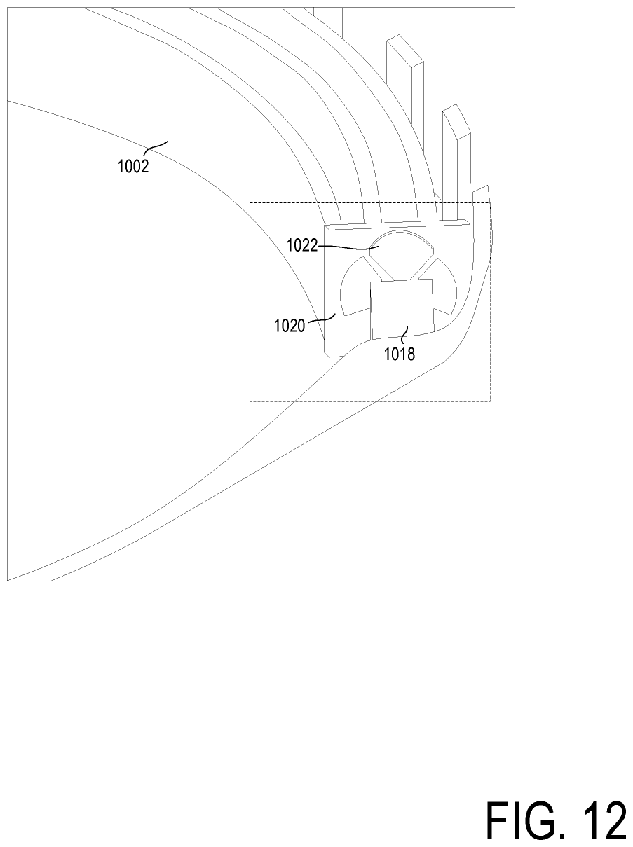

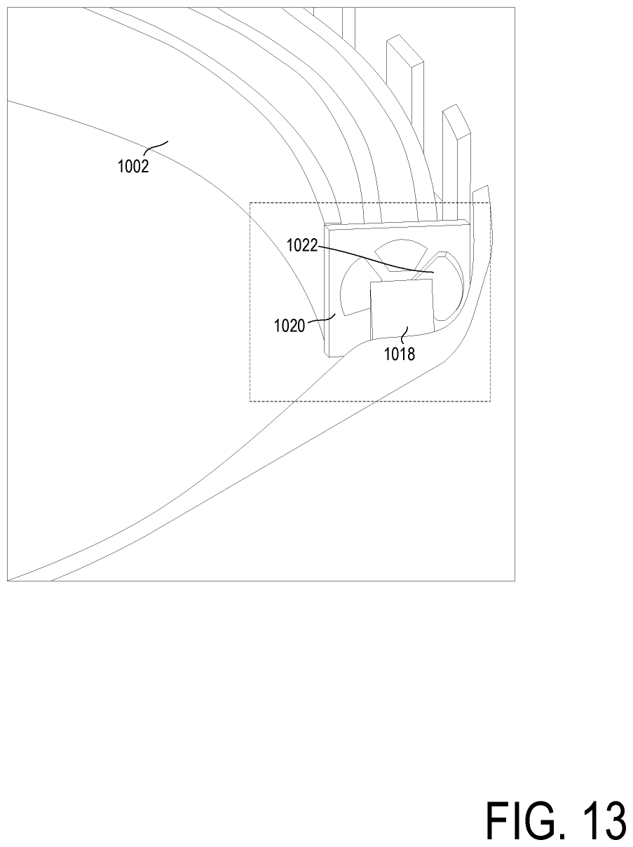

The motor assembly 1003 includes a motor 1018, a vent barrier 1020, and a flange 1022. An exploded view of the motor assembly 1003 is shown in the zoomed-in view in FIG. 11. The flange 1022 defines several openings to the vent channels 1004, 1006, 1008. The motor 1018 can move the vent barrier 1020 to allow or prevent airflow to one or more of the vent channels 1004, 1006, 1008. For example, in one embodiment, the motor 1018 may position the vent barrier 1020 on the flange 1022 to block airflow to vent channel 1004, while allowing airflow to vent channels 1006, 1008, as shown in FIG. 11. The motor 1018 may position the vent barrier 1020 in another orientation on the flange 1022 to block airflow to vent channel 1006, while allowing airflow to vent channels 1004, 1008, as shown in FIG. 12. The motor 1018 may position the vent barrier 1020 in another orientation on the flange 1022 to block airflow to vent channel 1008, while allowing airflow to vent channels 1004, 1006, as shown in FIG. 13.

The vents 1010, 1012, 1014, 1016 may be arranged so that airflow passes on components of the compute device 100 that may require cooling, such as components 308, 310. In some embodiments, the vents 1010, 1012, 1014, 1016 may be arranged so that components that tend not to require cooling at the same time are not cooled at the same time, while components that tend to require cooling at the same time may be able to be cooled at the same time. In use, the compute device 100 can control which components receive cooling through the vents 1010, 1012, 1014, 1016 by using the motor 1018 to move the vent barrier 1020.

It should be appreciated that the configuration shown in FIGS. 10-13 is merely one possible configuration for the vent barrier 1020 and the vent channels 1004, 1006, 1008. In other embodiments, any suitable number of vent channels 1004, 1006, 1008 may be used, such as 1-10. Similarly, any suitable vent barrier 1020 or combination of vent barriers 1020 may be used to control airflow through the vent channels 1004, 1006, 1008. In some embodiments, the vent barrier 1020 may be able to be positioned to block all of the vent channels 1004, 1006, 1008, and/or be able to be positioned to not block any of the vent channels 1004, 1006, 1008.

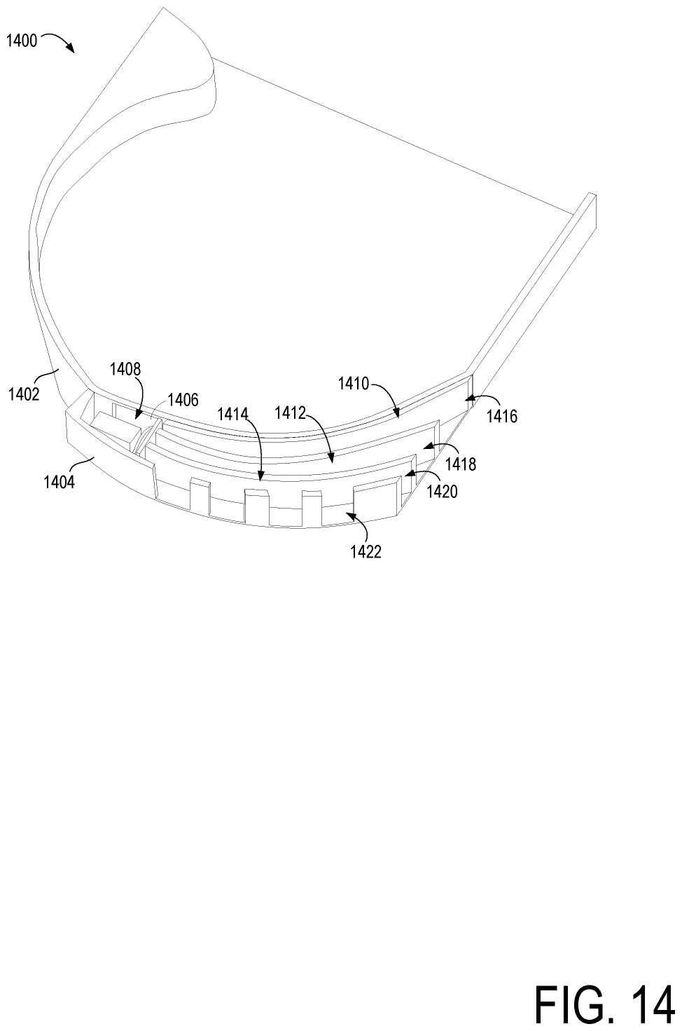

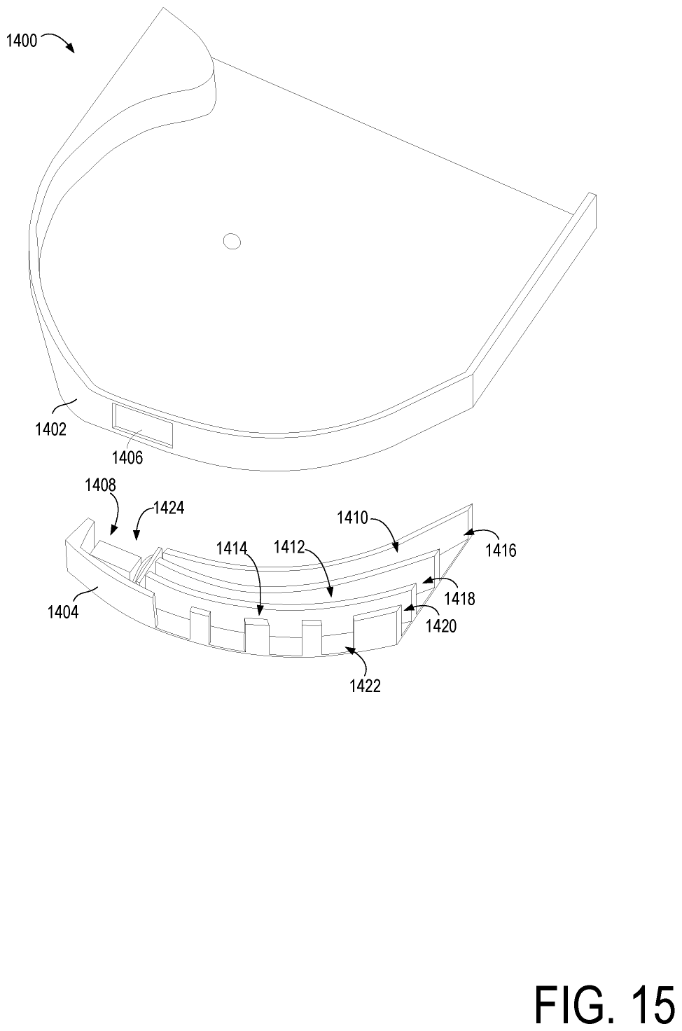

Referring now to FIGS. 14 and 15, in one embodiment, a fan assembly 1400 is shown. The fan assembly 1400 may be integrated into a compute device 100 in a similar manner as the fan assembly 300. The fan assembly 1400 includes a fan housing 1402. The fan and top cover are not shown in FIG. 14 in the interest of clarity, but the fan for the fan assembly 1400 may be similar to the fan 304 for the fan housing 302. A side vent 1406 is defined in the fan housing 1402.

A fan channel module 1404 is attached to the fan assembly 1400. An intake 1424 defined in the fan channel module 1404 is aligned with the side vent 1406. The fan channel module 1404 include vent channels 1410, 1412, 1414 with corresponding vents 1416, 1418, and 1420 and 1422. A motor assembly 1408 is positioned at one end of the vent channels 1410, 1412, 1414. The motor assembly 1408 may include a motor, a vent barrier, and a flange, similar to the motor assembly 1003. The fan channel module 1404 is a distinct component from the fan housing 1402, and, in some embodiments, may be detachable from the fan housing 1402, as shown in FIG. 15. The fan channel module 1404 may attach to the fan housing 1402 in any suitable manner, such as through hooks or magnets. In some embodiments, the fan channel module 1404 may be permanently fixed to the fan housing 1402 once it is attached. In other embodiments, the fan channel module 1404 may be removably attached to the fan housing 1402.

In use, air can flow from the fan housing 1402 through the side vent 1406 and into the fan channel module 1404 through the intake 1424. Air can pass through the vent channels 1410, 1412, 1414 and be directed to components of the compute device 100, or the motor can position the vent barrier to block one, some, or all of the vent channels 1410, 1412, 1414, as described above in regard to FIGS. 10-13.

Different variations of the fan channel module 1404 may be used with the same fan housing 1402. For example, one embodiment of a fan channel module 1404 may have two vent channels directing air to two components in particular locations that require cooling. In another embodiment, a fan channel module 1404 may have three vent channels directing air to three components in different locations that require cooling. The particular vent channels and corresponding vents may be chosen based on positioning and cooling requirements of components of the compute device 100, while relying on the same modular design of the fan housing 1402. Such an approach may reduce costs and increase flexibility. In some embodiments, the motor assembly 1408 may be removed, allowing for airflow to all of the vent channels of the fan channel module 1404.

It should be appreciated that the various embodiments described above can be used together. For example, in one embodiment, a fan channel module 1404 may include a motor assembly 1408 to control which vent channels 1410, 1412, 1414 receive airflow, and the fan channel module 1404 may also include vent covers similar to those described in FIGS. 3-9, allowing for additional control of airflow.

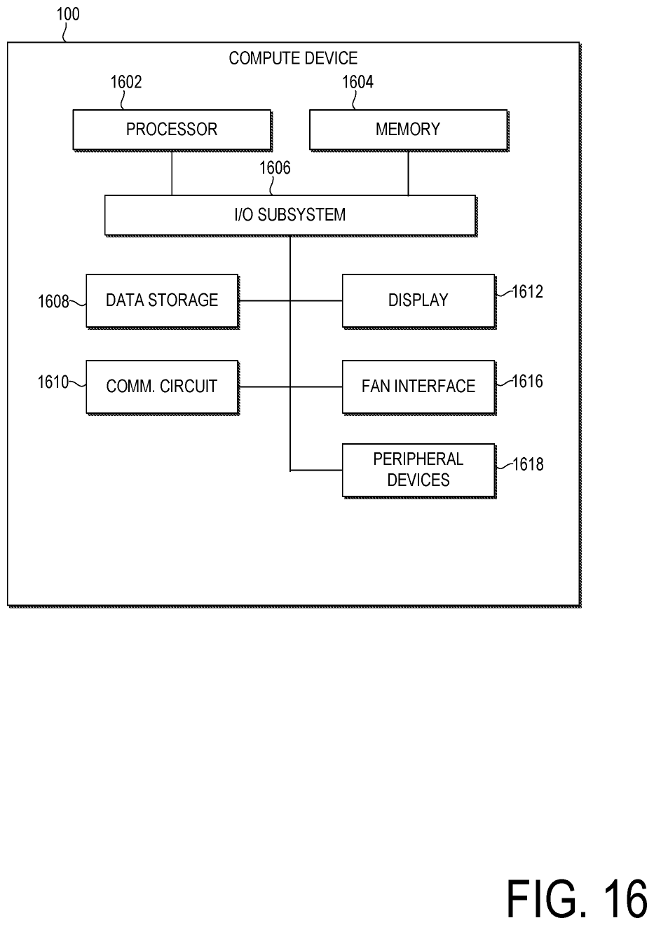

Referring now to FIG. 16, in one embodiment, components of the compute device 100 are shown. The compute device 100 may be embodied as any type of compute device. For example, the compute device 100 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a networked computer, a wearable computer, a handset, a messaging device, a camera device, and/or any other compute device. In some embodiments, the compute device 100 may be located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

The illustrative compute device 100 includes a processor 1602, a memory 1604, an input/output (I/O) subsystem 1606, data storage 1608, a communication circuit 1610, a display 1612, a fan interface 1616, and one or more peripheral devices 1618. In some embodiments, one or more of the illustrative components of the compute device 100 may be incorporated in, or otherwise form a portion of, another component. For example, the memory 1604, or portions thereof, may be incorporated in the processor 1602 in some embodiments. In some embodiments, one or more of the illustrative components may be physically separated from another component.

The processor 1602 may be embodied as any type of processor capable of performing the functions described herein. For example, the processor 1602 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 1604 may be embodied as any type of volatile or non-volatile memory or data storage capable of performing the functions described herein. In operation, the memory 1604 may store various data and software used during operation of the compute device 100 such as operating systems, applications, programs, libraries, and drivers. The memory 1604 is communicatively coupled to the processor 1602 via the I/O subsystem 1606, which may be embodied as circuitry and/or components to facilitate input/output operations with the processor 1602, the memory 1604, and other components of the compute device 100. For example, the I/O subsystem 1606 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. The I/O subsystem 1606 may connect various internal and external components of the compute device 100 to each other with use of any suitable connector, interconnect, bus, protocol, etc., such as an SoC fabric, PCIe®, USB2, USB3, USB4, NVMe®, Thunderbolt®, and/or the like. In some embodiments, the I/O subsystem 1606 may form a portion of a system-on-a-chip (SoC) and be incorporated, along with the processor 1602, the memory 1604, and other components of the compute device 100 on a single integrated circuit chip.

The data storage 1608 may be embodied as any type of device or devices configured for the short-term or long-term storage of data. For example, the data storage 1608 may include any one or more memory devices and circuits, memory cards, hard disk drives, solid-state drives, or other data storage devices.

The communication circuit 1610 may be embodied as any type of interface capable of interfacing the compute device 100 with other compute devices, such as over one or more wired or wireless connections. In some embodiments, the communication circuit 1610 may be capable of interfacing with any appropriate cable type, such as an electrical cable or an optical cable. The communication circuit 1610 may be configured to use any one or more communication technology and associated protocols (e.g., Ethernet, Bluetooth®, Wi-Fi®, WiMAX, near field communication (NFC), etc.). The communication circuit 1610 may be located on silicon separate from the processor 1602, or the communication circuit 1610 may be included in a multi-chip package with the processor 1602, or even on the same die as the processor 1602. The communication circuit 1610 may be embodied as one or more add-in-boards, daughtercards, network interface cards, controller chips, chipsets, specialized components such as a field programmable gate array (FPGA) or application specific integrated circuit (ASIC), or other devices that may be used by the compute device 1602 to connect with another compute device. In some embodiments, communication circuit 1610 may be embodied as part of a system-on-a-chip (SoC) that includes one or more processors, or included on a multichip package that also contains one or more processors. In some embodiments, the communication circuit 1610 may include a local processor (not shown) and/or a local memory (not shown) that are both local to the communication circuit 1610. In such embodiments, the local processor of the communication circuit 1610 may be capable of performing one or more of the functions of the processor 1602 described herein. Additionally or alternatively, in such embodiments, the local memory of the communication circuit 1610 may be integrated into one or more components of the compute device 1602 at the board level, socket level, chip level, and/or other levels.

The display 1612 may include one or more embedded or wired or wirelessly connected external visual indicators, such as a heads-up display, a computer monitor, a projector, a touchscreen display, a liquid crystal display (LCD), a light-emitting diode display, or a flat panel display.

The fan interface 1616 is connected to one or more fans, such as the fan 304. The fan interface 1616 may be able to turn the fan 304 on and off, control the speed of the fan 304, read the speed of the fan 304, etc.

In some embodiments, the compute device 100 may include other or additional components, such as those commonly found in a compute device. For example, the compute device 100 may also have peripheral devices 1618, such as a keyboard, a mouse, a speaker, an external storage device, etc. In some embodiments, the compute device 100 may be connected to a dock that can interface with various devices, including peripheral devices 1618. The compute device 100 may include several additional components, such as a battery, one or more antennas, one or more connectors (such as one or more USB2 connectors, one or more USB3 connectors, an SD card slot, a headphone and/or microphone jack, a power connector, etc.), etc. Each of those various components may be in the lid portion 102 and/or the base portion 104, as appropriate.

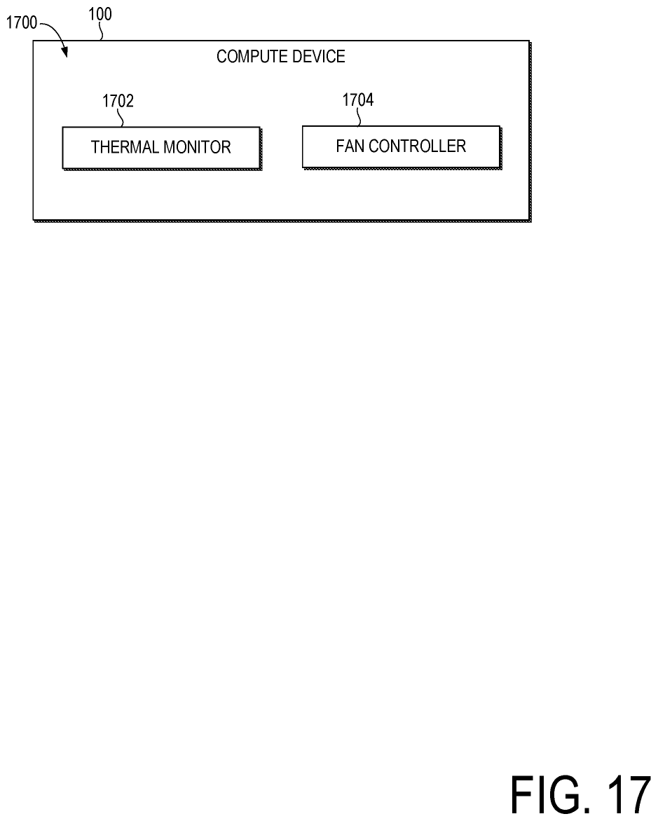

Referring now to FIG. 17, in an illustrative embodiment, the compute device 100 establishes an environment 1700 during operation. The illustrative environment 1700 includes a thermal monitor 1702 and a fan controller 1704. The various modules of the environment 1700 may be embodied as hardware, software, firmware, or a combination thereof. For example, the various modules, logic, and other components of the environment 1700 may form a portion of, or otherwise be established by, the processor 1602, the memory 1604, the data storage 1608, or other hardware components of the compute device 100. As such, in some embodiments, one or more of the modules of the environment 1700 may be embodied as circuitry or collection of electrical devices (e.g., thermal monitor circuitry 1702, fan controller circuitry 1704, etc.). It should be appreciated that, in such embodiments, one or more of the circuits (e.g., the thermal monitor circuitry 1702, the fan controller circuitry 1704, etc.) may form a portion of one or more of the processor 1602, the memory 1604, the I/O subsystem 1606, the data storage 1608, and/or other components of the compute device 100. For example, in some embodiments, some or all of the modules may be embodied as the processor 1602, as well as the memory 1604 and/or data storage 1608 storing instructions to be executed by the processor 1602. Additionally, in some embodiments, one or more of the illustrative modules may form a portion of another module and/or one or more of the illustrative modules may be independent of one another. Further, in some embodiments, one or more of the modules of the environment 1700 may be embodied as virtualized hardware components or emulated architecture, which may be established and maintained by the processor 1602 or other components of the compute device 100. It should be appreciated that some of the functionality of one or more of the modules of the environment 1700 may require a hardware implementation, in which case embodiments of modules that implement such functionality will be embodied at least partially as hardware.

The thermal monitor 1702, which may be embodied as hardware, firmware, software, virtualized hardware, emulated architecture, and/or a combination thereof as discussed above, is configured to sense temperatures of various components of the compute device 100. The thermal monitor 1702 may read temperature data from temperature sensors integrated into various components of the compute device 100. In some embodiments, the thermal monitor 1702 may predict thermal dissipation of various components depending on the workload of the compute device 100.

The fan controller 1704, which may be embodied as hardware, firmware, software, virtualized hardware, emulated architecture, and/or a combination thereof as discussed above, is configured to control one or more fans of the compute device 100, such as the fan 304. The fan controller 1704 may increase fan speed when temperature of components such as the processor 1602 or memory 1604 are high. Additionally or alternatively, the fan controller 1704 may increase fan speed to force vent covers (such as vent covers 316, 318, 602, 604, 902, 904) to allow air to flow over various components, such as components 308, 310. The fan controller 1704 may be programmed with a threshold fan speed over which the vent covers may open. Additionally or alternatively, in some embodiments, the fan controller 1704 can controller a motor, such as motor 1018, to move a vent barrier 1020 to block or unblock various vent channels 1004, 1006, 1008.

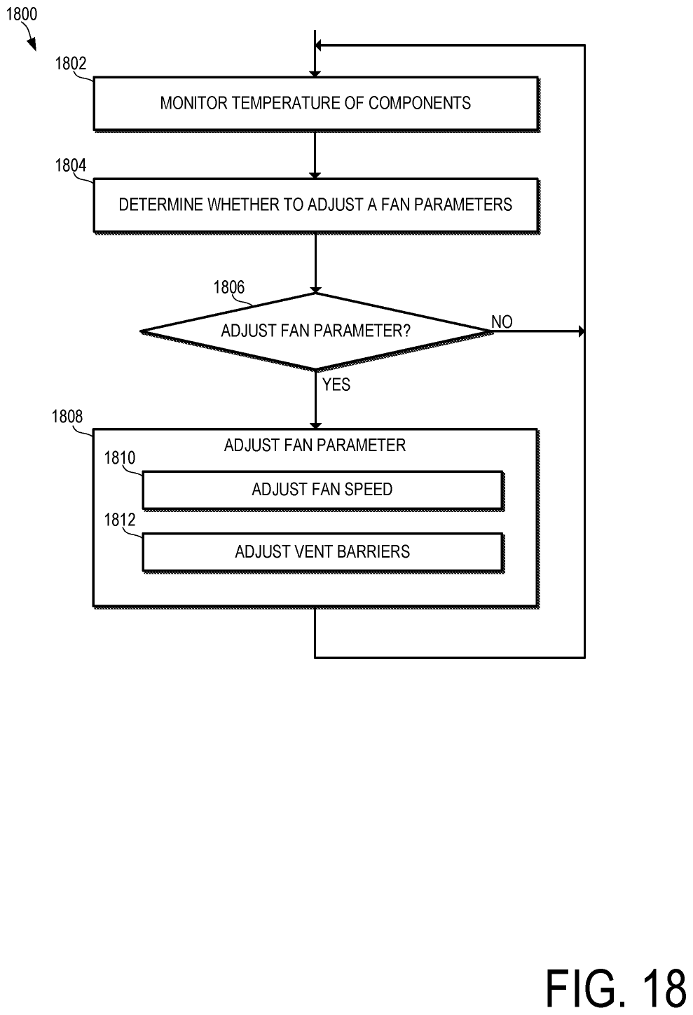

Referring now to FIG. 18, in one embodiment, a flowchart for a method 1800 for controlling a fan 304 of a compute device 100. The method 1800 begins in block 1802, in which the compute device 100 monitors temperatures of various components of the compute device 100, such as a processor 1602, a memory 1604, data storage 1608, etc.

In block 1804, the compute device 100 determines whether to adjust one or more fan parameters. Fan parameters may be, e.g., fan speed or a position of a vent barrier 1020. The compute device 100 may determine that a fan speed should be increased in a component is too hot or that a component should be cooled off. In some embodiments, the compute device 100 may determine that a component requires cooling based on a workload. For example, a component may require additional cooling when a workload requires heavy use of that component, and the compute device 100 may determine that a parameter should be changed in order to provide airflow to that component.

In block 1806, if a fan parameter is not to be adjusted, the method 1800 loops back to block 1802 to continue monitoring the temperature of various components. If a fan parameter is to be adjusted, the method 1800 proceeds to block 1808.

In block 1808, the compute device 100 adjusts a fan parameter. In block 1810, the compute device 100 adjusts a fan speed. The compute device 100 may adjust a fan speed to increase airflow and/or to open a vent cover (such as vent cover 316, 318, 602, 604, 902, 904) in block 1810. The compute device 100 may also reduce fan speed if less cooling is required or if a vent cover can be closed. The compute device 100 may adjust one or more vent barriers 1020 in block 1812 in order to control airflow to various components. The method 1800 then loops back to block 1802 to continue monitoring the temperature of components of the compute device 100.

### Examples

Illustrative examples of the technologies disclosed herein are provided below. An embodiment of the technologies may include any one or more, and any combination of, the examples described below.

Example 1 includes a fan assembly comprising a fan housing comprising an intake and a side vent; a variable-speed fan disposed in the fan housing; and a vent cover disposed over the side vent, wherein the vent cover is operable to open in response to a speed of the variable-speed fan passing a threshold.

Example 2 includes the subject matter of Example 1, and wherein the vent cover is composed of fabric.

Example 3 includes the subject matter of any of Examples 1 and 2, and wherein the vent cover is adhered to the fan housing.

Example 4 includes the subject matter of any of Examples 1-3, and further including one or more torsion springs, wherein the one or more torsion springs apply a force to keep the vent cover closed while the speed of the variable-speed fan is below the threshold.

Example 5 includes the subject matter of any of Examples 1-4, and wherein the vent cover is composed of mylar.

Example 6 includes the subject matter of any of Examples 1-5, and further including one or more magnets disposed along an edge of the side vent, wherein the vent cover is magnetic, wherein the one or more magnets apply a force to keep the vent cover closed while the speed of the variable-speed fan is below the threshold.

Example 7 includes the subject matter of any of Examples 1-6, and wherein the fan housing further comprises a primary vent, wherein airflow through the primary vent is directed to a heat sink, wherein the heat sink is thermally coupled to a processor of a compute device.

Example 8 includes a system comprising the fan assembly of Example 7, further comprising the compute device, the heat sink, and the processor.

Example 9 includes the subject matter of Example 8, and wherein a plurality of vent channels are defined in the fan housing, further comprising a motor assembly comprising a motor; and a vent barrier connected to the motor, wherein the motor is able to move the vent barrier to block or unblock one or more of the plurality of vent channels.

Example 10 includes the subject matter of any of Examples 8 and 9, and wherein the vent barrier has a first configuration, a second configuration, and a third configuration, wherein, in the first configuration, the vent barrier blocks a first vent channel of the plurality of vent channels and unblocks a second vent channel or a third vent channel of the plurality of vent channels, wherein, in the second configuration, the vent barrier blocks the second vent channel of the plurality of vent channels and unblocks the first vent channel or the third vent channel, wherein, in the third configuration, the vent barrier blocks the third vent channel of the plurality of vent channels and unblocks the first vent channel or the second vent channel.

Example 11 includes the subject matter of any of Examples 8-10, and further including a fan channel module comprises an intake, wherein the fan channel module comprises one or more vent channels, wherein the fan channel module is attached to the fan housing, wherein the intake of the fan channel module is aligned to the side vent of the fan housing.

Example 12 includes the subject matter of any of Examples 8-11, and wherein the fan channel module is removably attached to the fan housing.

Example 13 includes a compute device comprising the fan assembly of Example 1; a processor; a memory coupled to the processor; and one or more computer-readable media comprising a plurality of instructions stored thereon that, when executed by the processor, cause the processor to monitor a temperature of one or more component of the compute device; determine to open the vent cover based on the monitored temperature of the one or more components; and increase a speed of the variable-speed fan to open the vent cover in response to the determination to open the vent cover.

Example 14 includes a fan assembly comprising a fan housing comprising an intake and a plurality of vent channels; a fan disposed in the fan housing; and a motor assembly comprising a motor; and a vent barrier connected to the motor, wherein the motor is operable to move the vent barrier to block or unblock one or more of the plurality of vent channels.

Example 15 includes the subject matter of Example 14, and wherein the vent barrier has a first configuration, a second configuration, and a third configuration, wherein, in the first configuration, the vent barrier blocks a first vent channel of the plurality of vent channels and unblocks a second vent channel or a third vent channel of the plurality of vent channels, wherein, in the second configuration, the vent barrier blocks the second vent channel of the plurality of vent channels and unblocks the first vent channel or the third vent channel, wherein, in the third configuration, the vent barrier blocks the third vent channel of the plurality of vent channels and unblocks the first vent channel or the second vent channel.

Example 16 includes the subject matter of any of Examples 14 and 15, and wherein a primary vent is defined in the fan housing, wherein airflow through the primary vent is directed to a heat sink, wherein the heat sink is thermally coupled to a processor of a compute device.

Example 17 includes a system comprising the fan assembly of Example 16, further comprising the compute device, the heat sink, and the processor.

Example 18 includes a fan assembly comprising a fan housing comprising an intake and a side vent; and a fan channel module comprising an intake and one or more vent channels, wherein the fan channel module is attached to the fan housing, wherein the intake of the fan channel module is aligned to the side vent of the fan housing.

Example 19 includes the subject matter of Example 18, and wherein the fan channel module is removably attached to the fan housing.

Example 20 includes the subject matter of any of Examples 18 and 19, and further including a motor assembly comprising a motor; and a vent barrier connected to the motor, wherein the motor is operable to move the vent barrier to block or unblock one or more of the one or more vent channels.

Example 21 includes the subject matter of any of Examples 18-20, and wherein the fan housing comprises a primary vent, wherein airflow through the primary vent is directed to a heat sink, wherein the heat sink is thermally coupled to a processor of a compute device.

Example 22 includes a system comprising the fan assembly of Example 21, further comprising the compute device, the heat sink, and the processor.

1. A fan assembly comprising:
a fan housing comprising an intake and a side vent;
a variable-speed fan disposed in the fan housing; and
a vent cover disposed over the side vent, wherein the vent cover is operable to open in response to a speed of the variable-speed fan passing a threshold.

2. The fan assembly of claim 1, wherein the vent cover is composed of fabric.

3. The fan assembly of claim 2, wherein the vent cover is adhered to the fan housing.

4. The fan assembly of claim 1, further comprising one or more torsion springs, wherein the one or more torsion springs apply a force to keep the vent cover closed while the speed of the variable-speed fan is below the threshold.

5. The fan assembly of claim 4, wherein the vent cover is composed of mylar.

6. The fan assembly of claim 1, further comprising one or more magnets disposed along an edge of the side vent, wherein the vent cover is magnetic, wherein the one or more magnets apply a force to keep the vent cover closed while the speed of the variable-speed fan is below the threshold.

7. The fan assembly of claim 1, wherein the fan housing further comprises a primary vent, wherein airflow through the primary vent is directed to a heat sink, wherein the heat sink is thermally coupled to a processor of a compute device.

8. A system comprising the fan assembly of claim 7, further comprising the compute device, the heat sink, and the processor.

9. The fan assembly of claim 1, wherein a plurality of vent channels are defined in the fan housing,
further comprising a motor assembly comprising:
a motor; and
a vent barrier connected to the motor, wherein the motor is able to move the vent barrier to block or unblock one or more of the plurality of vent channels.

10. The fan assembly of claim 9, wherein the vent barrier has a first configuration, a second configuration, and a third configuration,
wherein, in the first configuration, the vent barrier blocks a first vent channel of the plurality of vent channels and unblocks a second vent channel or a third vent channel of the plurality of vent channels,
wherein, in the second configuration, the vent barrier blocks the second vent channel of the plurality of vent channels and unblocks the first vent channel or the third vent channel,
wherein, in the third configuration, the vent barrier blocks the third vent channel of the plurality of vent channels and unblocks the first vent channel or the second vent channel.

11. The fan assembly of claim 1, further comprising
a fan channel module comprises an intake, wherein the fan channel module comprises one or more vent channels, wherein the fan channel module is attached to the fan housing, wherein the intake of the fan channel module is aligned to the side vent of the fan housing.

12. The fan assembly of claim 11, wherein the fan channel module is removably attached to the fan housing.

13. A compute device comprising:
the fan assembly of claim 1;
a processor;
a memory coupled to the processor; and
one or more computer-readable media comprising a plurality of instructions stored thereon that, when executed by the processor, cause the processor to:
monitor a temperature of one or more component of the compute device;
determine to open the vent cover based on the monitored temperature of the one or more components; and
increase a speed of the variable-speed fan to open the vent cover in response to the determination to open the vent cover.

14. A fan assembly comprising:
a fan housing comprising an intake and a plurality of vent channels;
a fan disposed in the fan housing; and
a motor assembly comprising:
a motor; and
a vent barrier connected to the motor, wherein the motor is operable to move the vent barrier to block or unblock one or more of the plurality of vent channels.

15. The fan assembly of claim 14, wherein the vent barrier has a first configuration, a second configuration, and a third configuration,
wherein, in the first configuration, the vent barrier blocks a first vent channel of the plurality of vent channels and unblocks a second vent channel or a third vent channel of the plurality of vent channels,
wherein, in the second configuration, the vent barrier blocks the second vent channel of the plurality of vent channels and unblocks the first vent channel or the third vent channel,
wherein, in the third configuration, the vent barrier blocks the third vent channel of the plurality of vent channels and unblocks the first vent channel or the second vent channel.

16. The fan assembly of claim 14, wherein a primary vent is defined in the fan housing, wherein airflow through the primary vent is directed to a heat sink, wherein the heat sink is thermally coupled to a processor of a compute device.

17. A system comprising the fan assembly of claim 16, further comprising the compute device, the heat sink, and the processor.

18. A fan assembly comprising:
a fan housing comprising an intake and a side vent; and
a fan channel module comprising an intake and one or more vent channels, wherein the fan channel module is attached to the fan housing, wherein the intake of the fan channel module is aligned to the side vent of the fan housing.

19. The fan assembly of claim 18, wherein the fan channel module is removably attached to the fan housing.

20. The fan assembly of claim 18, further comprising:
a motor assembly comprising:
a motor; and
a vent barrier connected to the motor, wherein the motor is operable to move the vent barrier to block or unblock one or more of the one or more vent channels.

21. The fan assembly of claim 18, wherein the fan housing comprises a primary vent, wherein airflow through the primary vent is directed to a heat sink, wherein the heat sink is thermally coupled to a processor of a compute device.

22. A system comprising the fan assembly of claim 21, further comprising the compute
device, the heat sink, and the processor.
